(19) United States
(12) Patent Application Publication
(10) Pub. No.: US 2015/0035055 A1
(43) Pub. Date: Feb. 5, 2015

(54) SEMICONDUCTOR DEVICE AND MANUFACTURING METHOD THEREFOR

(71) Applicant: Guilei Wang, Beijing (CN)

(72) Inventor: Guilei Wang, Beijing (CN)

(73) Assignee: INSTITUTE OF MICROELECTORNICS, CHINESE ACADEMY OF SCIENCES, Beijing (CN)

(21) Appl. No.: 14/361,692

(22) PCT Filed: Aug. 3, 2012
(86) PCT No.: PCT/CN2012/079691

§ 371 Date: May 29, 2014

(30) Foreign Application Priority Data
Dec. 1, 2011 (CN) 201110394014.2

(51) Int. Cl. H01L 29/10; H01L 29/78; H01L 29/66

(52) U.S. Cl. CPC H01L 29/1054; H01L 29/66689; H01L 29/7816; H01L 29/66545; H01L 29/665; H01L 29/66575
USPC 257/339; 438/299

(57) ABSTRACT

A method for manufacturing a semiconductor device includes providing a substrate, forming a pseudo-gate stack and sidewalls on the substrate, forming an S/D region on both sides of the pseudo-gate stack, and forming a stop layer and a first interlayer dielectric layer covering the entire semiconductor device; removing part of the stop layer to expose the pseudo-gate stack, and further removing the pseudo-gate stack to expose the channel region; etching the channel region to form a groove structure; forming a new channel region to flush with the upper surface of the substrate, wherein the new channel region includes a buffer layer, a Ge layer, and a Si cap layer; forming a gate stack. Accordingly, the present application also discloses a semiconductor device. The present application can effectively improve the carrier mobility and the performance of the semiconductor device by replacing Si with Ge to form a new channel region.

### CROSS-REFERENCE TO RELATED APPLICATION

This application claims priority to the Chinese Patent Application No. 201110394014.2, filed on Dec. 1, 2011, entitled “semiconductor device and method for manufacturing the same”, which is incorporated herein by reference in its entirety.

### TECHNICAL FIELD

The present disclosure relates to the field of semiconductor technology, and in particular, to a semiconductor device and a method for manufacturing the same.

### BACKGROUND

With the development of semiconductor industry, integrated circuit with higher performance and more functionality requires higher device density and further decrease in the size and space of or between the components and units (currently nanoscale is reached). Therefore, process control is highly required in semiconductor device manufacturing process.

The main question in limiting the further scaling down of metal oxide semiconductor (MOS) transistor size is the short channel effect (SCE) and this phenomenon happens mainly as the channel length is less than 0.1 micrometer. Device failure includes but is not limited to DIBL (drain-induced carrier barrier lowering, i.e. low drain breakdown voltage), subthreshold leakage, and threshold instability, etc. All these problems are collectively referred to as short channel effect, which is mainly related to the equivalent oxide thickness (EOT) of the interface layer.

Therefore, with the further decrease in device size, it becomes the most important link in increasing the carrier mobility. In current technology, silicon materials are commonly used as the substrate for various semiconductor devices, wherein the silicon materials are used in the channel region. If the materials for the channel region can be replaced by materials with higher carrier mobility, and if this material combines well with the silicon substrate, the performance of semiconductor device will be significantly improved.

### SUMMARY OF THE DISCLOSURE

The purpose of the present disclosure is to provide a semiconductor device and a method for manufacturing the same to improve the carrier mobility in the channel region and to further improve the semiconductor device performance.

According to one aspect of the present disclosure, a method for manufacturing a semiconductor device is provided, the characteristics of which comprising the following stages:
a) providing an substrate (100), forming a dummy-gate stack and sidewalls (230) on the substrate (100), forming an S/D region (110) on both sides of the dummy-gate stack, and forming a stop layer (240) and a first interlayer dielectric layer (300) covering the entire semiconductor device;
b) removing part of the stop layer (240) to expose the dummy-gate stack, and further removing the dummy-gate stack to expose the channel region;
c) etching the channel region to form a groove structure;
d) forming a new channel region in the groove structure to flush with the upper surface of the substrate (100), wherein the new channel region comprising successively from the substrate interface layer a buffer layer, a Ge layer (120), and a Si cap layer;
e) forming a gate stack.

According to another aspect of the present disclosure, a semiconductor device is also provided, comprising:

An substrate (100), forming a channel region groove, in which a buffer layer, a Ge layer (120), and a Si cap layer are filled;

A gate stack, which is formed on the Si cap layer;

Sidewalls (230), which is formed on both sides of the gate stack;

An S/D region (110), which is formed in the substrate (100) on both sides of the channel region groove.

The semiconductor device manufacturing method and the structure of the same provided in the present disclosure is to improve the carrier mobility by epitaxially growing Ge to replace the conventional Si in the channel region, as shown in the following table:

| | Lattice | | Band | | |
|---|---|---|---|---|---|
| | Constant | Dielectric | Gap | Mobility (cm²/V-s) | |
| Material | (nm) | Constant | (eV) | Electron | Hole |
| Si | 0.5431 | 11.8 | 1.12 | 1600 | 430 |
| Ge | 0.5675 | 16 | 0.66 | 3900 | 1900 |
| GaAs | 0.5653 | 12.4 | 1.42 | 9200 | 400 |
| InAs | 0.6058 | 14.8 | 0.36 | 40000 | 500 |
| InSb | 0.648 | 17.7 | 0.17 | 77000 | 850 |

In several commonly used materials, Ge possesses the highest hole mobility and a higher electron mobility, therefore, both hole and electron mobilities will be improved by using Ge materials. The higher the carrier mobility, the higher the working speed of the large-scaled integrated circuits (LSIC). Furthermore, since Ge possesses similar lattice constant as Si, Ge can be easily integrated on Si substrate. B or In for NMOS devices and As or P for PMOS devices can be doped in-situ on Ge to further adjust the tension on channel region, and by using this in-situ doping method the damage caused by ion implantation can be effectively reduced. In addition, Ge doping will form a very steep doping profile and the short channel effect can be improved.

Therefore, by replacing Si with Ge in the channel region the carrier mobility in the channel region can be effectively improved and the entire performance of the device can also be improved. This method can be easily realized in industrial process.

### BRIEF DESCRIPTION OF THE DRAWINGS

Other characteristics, objectives and advantages will become more obvious after reading the detailed description of the non-limiting embodiments with reference to the following attached drawings, in which:

FIG. 1 is a schematic flow chart showing the method for manufacturing a semiconductor device according to an embodiment of the present disclosure;

FIGS. 2-13 are schematic cross-sectional views of the various stages for manufacturing the semiconductor device according to the flow chart in FIG. 1.

In the attached drawings, the same or similar reference numbers represent the same or similar components.

### DETAILED DESCRIPTION

In order to elucidate the purpose, technical solutions and advantages of the present disclosure, exemplary embodiments of the present disclosure will be described in more details below in combination with the attached drawings.

Exemplary embodiments of the present disclosure will be described in more details below. Some embodiments are illustrated in the attached drawings, in which the same or similar reference numbers represent the same or similar elements or the components having the same or similar functions. The following embodiments described with reference to the drawings are only exemplary for explaining the present invention, and therefore shall not be construed as limiting the present invention.

The disclosure below provides many different embodiments or examples to implement different structures of the present invention. In order to simplify the disclosure of the present invention, components and settings of specific examples are described below. Obviously, they are merely exemplary, and are not intended to limit the present invention. In addition, reference numbers and/or letters can be repeated in different examples of the invention. This repetition is used only for simplicity and clarity, and does not indicate any relationship between the discussed embodiments and/or settings. In addition, the invention provides a variety of specific examples of processes and materials, but it is obvious for a person of ordinary skill in the art that other processes can be applied and/or other materials can be used. In addition, the following description of a structure where a first feature is “on” a second feature can comprise examples where the first and second feature are in direct contact, and also can comprise examples where additional features are formed between the first and second features so that the first and second features may not be in direct contact. Note that the components in the attached drawings may not be drawn to scale. The description of the known components and processing technology is omitted in the present disclosure to avoid unnecessary limitation to the present disclosure.

As the semiconductor device provided in the present disclosure possesses several preferred structures, one of the preferred structures is provided and described below.

This semiconductor device comprises: an substrate 100, forming a channel region groove, in which a buffer layer, a Ge layer 120, and a Si cap layer are filled; a gate stack, which is formed on the Si cap layer; sidewalls 230, which is formed on both sides of the gate stack; an S/D region 110, which is formed in the substrate 100 on both sides of the channel region groove; a stop layer 240, which covers the S/D region 110 and the sidewalls 230; a first interlayer dielectric layer 300, which covers the stop layer 240. The depth of the stop layer 240 is 10 nm˜20 nm, such as 10 nm, 15 nm, or 20 nm. The buffer layer is SiₓGe₁₋ₓ, where 0<x<1. Different doping can be applied to the Ge layer 120 according to different device type, for example, in-situ doping B or In for NMOS devices and in-situ doping As or P for PMOS devices.

The gate stack comprises: a dielectric layer 410, a high k dielectric layer 420, and a metal gate 430, wherein the depth of the high k dielectric layer 420 is 1 nm˜3 nm, such as 1 nm, 2 nm, or 3 nm.

Optionally, it also comprises a second interlayer dielectric layer 500 and a contact plug 620. The second interlayer dielectric layer 500 covers the first interlayer dielectric layer 300 and the gate stack; the contact plug 620 penetrates the second interlayer dielectric layer 500, the first interlayer dielectric layer 300, and the stop layer 240, and connects with the S/D region 110. The depth of the second interlayer dielectric layer 500 is 10˜50 nm, such as 10 nm, 20 nm, or 50 nm.

Preferably, it also comprises a metal silicide 600 between the contact plug 620 and the S/D region 110. The depth of the metal silicide 600 is 1 nm˜7 nm, such as 1 nm, 4 nm, or 7 nm.

The above exemplary embodiments will be further described below in combination with the semiconductor device manufacturing method provided in the present disclosure.

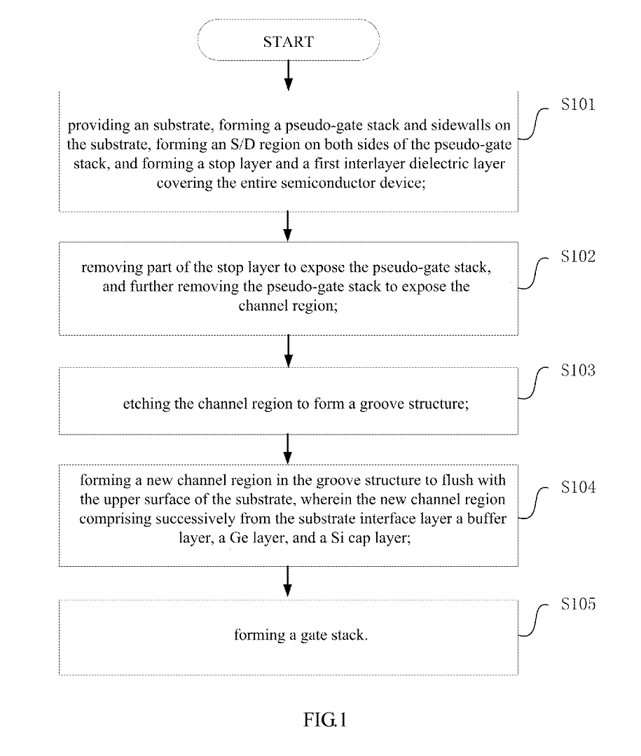

As referred to FIG. 1, which is the schematic flow chart showing the method for manufacturing a semiconductor device according to an exemplary embodiment of the present disclosure, it comprises:

Stage S101: providing an substrate 100, forming a pseudo-gate stack and sidewalls 230 on the substrate 100, forming an S/D region 110 on both sides of the pseudo-gate stack, and forming a stop layer 240 and a first interlayer dielectric layer 300 covering the entire semiconductor device;

Stage S102: removing part of the stop layer 240 to expose the pseudo-gate stack, and further removing the pseudo-gate stack to expose the channel region;

Stage S103: etching the channel region to form a groove structure;

Stage S104: forming a new channel region in the groove structure to flush with the upper surface of the substrate 100, wherein the new channel region comprising successively from the interface layer a buffer layer, a Ge layer 120, and a Si cap layer;

Stage S105: forming a gate stack.

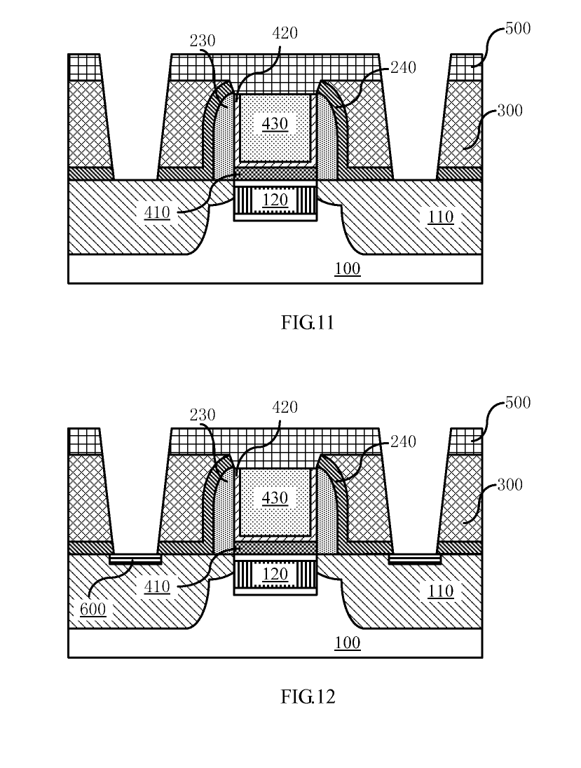

Stages S101 to S105 will be illustrated below in combination with FIGS. 2-13, which are schematic cross-sectional views of the various stages for manufacturing the semiconductor device according to the flow chart in FIG. 1. Note that the attached drawings in each embodiment are only for illustration purpose, so are not drawn to scale.

Stage S101 is executed as illustrated in FIG. 2. An substrate 100 is provided, a pseudo-gate stack and sidewalls 230 are formed on the substrate 100, an S/D region 110 is formed on both sides of the pseudo-gate stack, and a stop layer 240 and a first interlayer dielectric layer 300 is formed to cover the entire semiconductor device.

In current embodiment, the substrate 100 comprises silicon substrate (such as silicon wafers). According to the currently known design requirement (such as P-type substrate or N-type substrate), the substrate 100 can comprise all doping settings, or undoped intrinsic semiconductor. In other embodiments the substrate 100 can also comprise other basic semiconductor, such as Ge. Or the substrate 100 can comprise compound semiconductor, such as silicon carbide, gallium arsenide, indium arsenide or indium phosphide. Typically, the substrate 100 possesses but is not limited to a depth of about several hundred microns, such as in the depth range of 400 μm˜800 μm.

A dummy-gate stack comprising a dummy-gate 220 and a gate dielectric layer 210 is formed on the substrate 100. The materials for the gate dielectric layer 210 comprise but are not limited to thermal oxide layer, which comprises silicon oxide or silicon oxynitride. The dummy-gate 220 can be formed by polymer materials, which comprise polymethyl methacrylate, poly-carbonate, SU-8, polydimethylsiloxane, polyimide, poly-p-xylene, or combinations thereof. The formation method can be deposition, CVD, etc. For example, if SU-8 is used to form the dummy-gate 220, deposition method can be applied; since polyimide is photoresist, if polyimide is used to form the dummy-gate 220, spin-coating or exposure imaging methods can be applied. Preferably, amorphous silicon materials are used to form the dummy-gate 220.

In current embodiment, shallow doping to the substrate 100 on both sides of the dummy-gate stack is applied to form an S/D extension region before the sidewalls 230 are formed. Optionally, Halo-implantation can be applied to form a Halo implantation region, wherein the impurity type of the shallow doping is the same as the device type and the impurity type of the Halo-implantation is opposite to the device type.

Furthermore, sidewalls 230 are formed on the sidewalls of the pseudo-gate stack to separate the gates. Sidewalls 230 can be silicon nitride, silicon oxide, silicon oxynitride, silicon carbide, or combinations thereof, and/or formed by other suitable materials. Sidewalls 230 can possess multi-layer structure. Sidewalls 230 can be formed by processes including deposition etching with a depth range of 10 nm˜100 nm, such as 30 nm, 50 nm, or 80 nm.

Afterwards, an S/D region 110 is formed by implanting P-type or N-type dopants or impurities to the substrate 100. For example, the S/D region 110 can be P-type doped SiGe for PMOS devices and N-type doped silicon for NMOS devices. The S/D region 110 can be formed by methods including photoresist, ion-implantation, diffusion, and/or other suitable processes. In current embodiment, the S/D region 110 is inside the substrate 100, while in some other embodiments, the S/D region 110 can be an enhanced S/D structure formed by selective epitaxial growth, where the top of the epitaxial part is higher than the bottom of the dummy-gate stack (in this manual the bottom of the pseudo-gate stack refers to the boundary line between the pseudo-gate stack and the semiconductor substrate 100).

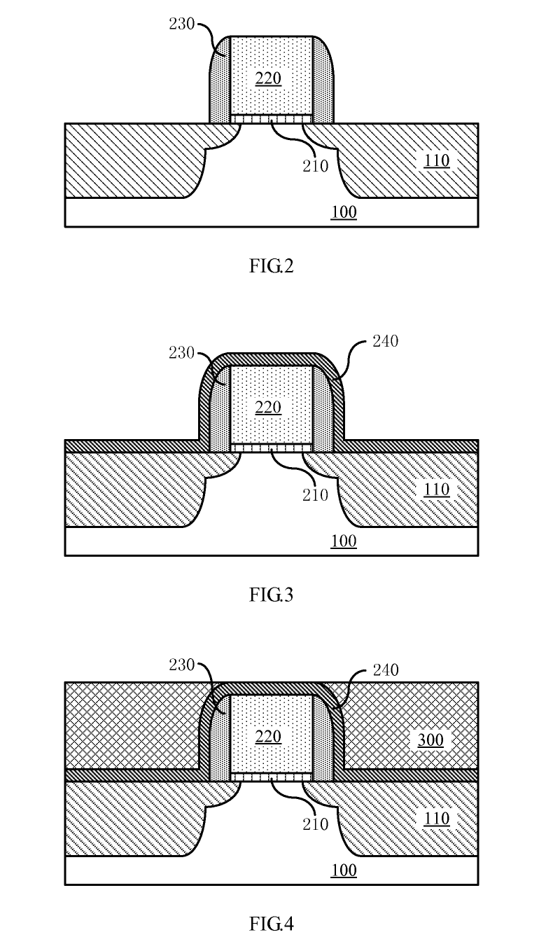

As referred to FIG. 3, a stop layer 240 is formed to cover the S/D region 110, the S/D extension region, the dummy-gate stack, and the sidewalls 230. The stop layer 240 can be made of materials including Si₃N₄, silicon oxynitride, silicon carbide, and/or other suitable materials. The stop layer 240 can be formed by methods including CVD, physical vapor deposition (PVD), ALD, and/or other suitable processes. In one embodiment, the depth of the stop layer 240 is 10 nm˜20 nm, such as 10 nm, 15 nm, or 20 nm. The stop layer 240 can be used not only as the stop layer for subsequent CMP stage, but also as a stress layer. Preferably, materials with tensile stress should be used to form the stop layer 240 in NMOS devices whereas materials with compressive stress should be used to form the stop layer 240 in PMOS devices.

A first interlayer dielectric layer 300 is formed to cover the stop layer 240. The first interlayer dielectric layer 300 can be formed on the stop layer 240 by methods including CVD, high density plasma CVD, spin-coating, or other suitable methods. The materials for the first interlayer dielectric layer 300 can be SiO₂, carbon doped SiO₂, BPSG, PSG, UGS, silicon oxynitride, low k materials or combinations thereof. The depth range of the first interlayer dielectric layer 300 can be 40 nm˜150 nm, such as 40 nm, 100 nm, or 150 nm. As illustrated in FIG. 4, planarization is executed to expose the stop layer 240 on the pseudo-gate stack to flush with the fist interlayer dielectric layer 300 (in the present disclosure, the nomenclature “flush with” means that the height difference between the former and latter is within the allowed process error).

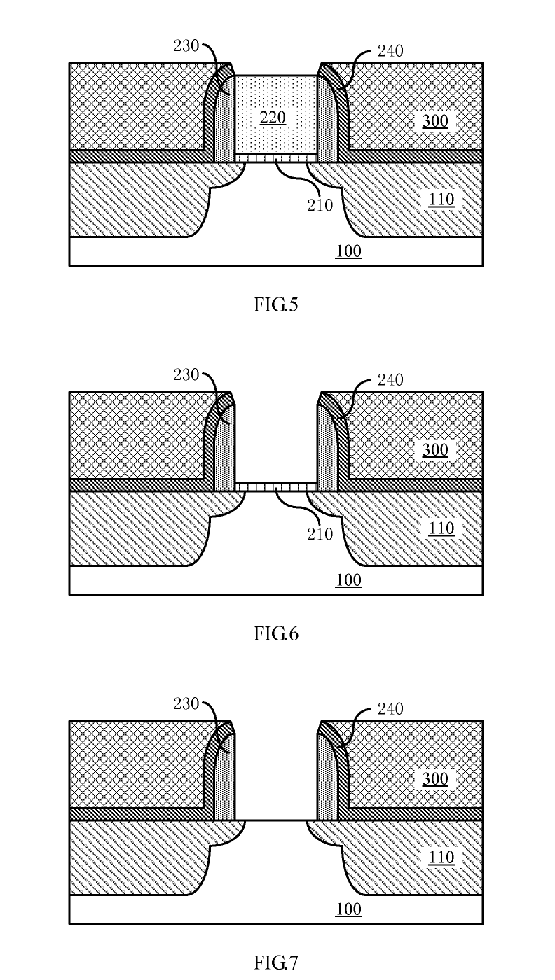

Stage S102 is executed, as referred to FIGS. 5 and 6, to remove part of the stop layer 240 to expose the pseudo-gate stack, and furthermore to remove the pseudo-gate stack to expose the channel region. The pseudo-gate 220 is removed and stopped at the gate dielectric layer 210 to form a groove. Since TMAH solution has high selectivity between amorphous silicon materials and silicon oxide materials, TMAH solution is preferably chosen to apply wet corrosion to remove the pseudo-gate 220, as referred to FIG. 6.

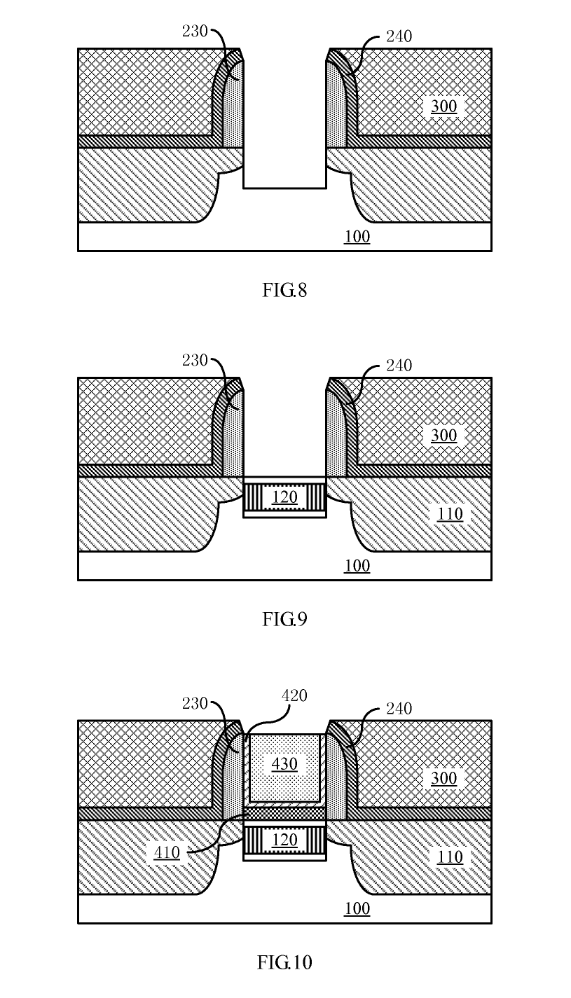

Next, as referred to FIG. 7, the gate dielectric layer 210 is removed and stopped at the substrate 100 to expose the channel region by either dry etching or wet corrosion. The wet corrosion process includes using HF-based wet corrosive solution, such as diluted HF acid (DHF), release corrosive solution (mixture of BOE, HF, and NH₄F), or other suitable corrosive solution. The dry etching methods include plasma etching, ion milling, reverse sputtering, reactive ion etching.

Furthermore, stage S103 is executed by further etching downwards from the groove formed in stage S102 to etch the channel region in the substrate 100 to form a channel region groove, as illustrated in FIG. 8. The etching method, for example, can be TMAH wet corrosion or plasma dry etching, to etch the substrate until a certain depth is reached. The method can be found above in this manual, and will not go into details herein. The depth of the channel region groove should be determined according to the device electrical performance; for example, when the depth of the device channel region is required to be 50 nm, the depth of the channel region groove should be greater than or equal to 50 nm.

As referred to FIG. 9, stage S104 is executed to form a new channel region in the channel region groove. First, SiₓGe₁₋ₓ material is deposited in the groove on the substrate 100 to form a buffer layer, wherein x can be in the range of 0˜1 according to the process requirement. The deposition can be carried out using high pressure chemical vapor deposition (UHV/CVD), molecular beam epitaxy (MBE), reduced pressure chemical vapor deposition (RPCVD), or metal organic chemical vapor deposition (MOCVD), etc. Next, Ge material is epitaxially grown on the buffer layer to form a Ge layer 120. According to the difference in device type, different ion in-situ doping is carried out during the growth process. B or In is doped for NMOS devices; As or P is doped for PMOS devices. Finally, a Si cap layer is formed on the Ge layer 120, wherein the upper surface of the Si cap layer is flush with the upper surface of the S/D region 110. Since the electron and hole mobilities of Ge are obviously higher than those of Si, and the lattice constant of Ge is similar to that of Si, it is easy to deposite Ge on the Si substrate 100. Therefore, the new channel region formed by Ge ion can further adjust the tension in the channel region to improve the carrier mobility in the channel region.

Finally, stage S105 is executed to form a gate stack. Optionally, a pad dielectric layer 410 is formed on the channel region. The materials for the pad dielectric layer 410 can be SiO₂, carbon-doped SiO₂, BPSG, PSG, UGS, silicon oxynitride, low k materials, or combinations thereof. Preferably, oxides with a depth less than 1 nm are chosen.

A high k dielectric layer 420 is formed on the dielectric layer 410 and the groove sidewalls. The materials for the high k dielectric layer 420 comprise HfAlON, HfSiAlON, HfTaAlON, HfTiAlON, HfON, HfSiON, HfTaON, HfSiON, Al₂O₃, La₂O₃, ZrO₂, LaAlO, or combinations thereof, preferably, HfO₂, or La₂O₃. The depth of the high k dielectric layer 420 is 1 nm˜3 nm, such as 1 nm, 2 nm, or 3 nm.

Furthermore, a metal gate 430 is formed. Optionally, the metal gate 430 can be single layer or multi-layer structure. The materials can be TaN, TaC, TiN, TaAlN, TiAlN , MoAlN , TaTbN, TaErN, TaYbN, TaSiN, HfSiN, MoSiN, RuTaₓ, NiTaₓ, or combinations thereof. The depth range can be 10 nm˜80 nm, such as 10 nm, 30 nm, or 80 nm.

Optionally, the metal gate 430 can also comprise work functional metal layer, which can be made of TiN, TiAlN, TaN, or TaAlN, etc. The work functional metal layer is located on the bottom of the metal gate 430 and connects with the high k dielectric layer 420.

As referred to FIG. 10, planarization is executed to the high k dielectric layer 420 and the metal gate 430 to fill right in the groove on the sidewalls 230, the upper surfaces of both flushing with the upper surface of the sidewalls.

Optionally, a contact plug is formed on the semiconductor device formed in stage S105. First a second interlayer dielectric layer 500 is formed to cover the semiconductor device formed in the above stages. The second interlayer dielectric layer 500 can be formed by methods including chemical vapor deposition (CVD), high density plasma CVD, spin-coating, or other suitable methods. The materials of the second interlayer dielectric layer 500 can comprise SiO₂, carbon-doped SiO₂, BPSG, PSG, UGS, silicon oxynitride, low k materials, or combinations thereof. The depth range of the second interlayer dielectric layer 500 is 10 nm˜50 nm, such as 10 nm, 30 nm, or 50 nm.

Next, as referred to FIG. 11, part of the second interlayer dielectric layer 500, the first interlayer dielectric layer 300, and the stop layer 240 is etched to form a contact hole to expose part of the S/D region 110. Specifically, the contact hole can be formed by dry etching, wet corrosion, or other suitable etching methods. Since the gate stack is protected by the sidewalls 230, short circuit of the metal gate 430 and the S/D region 110 will not happen even over etching during the formation of the contact hole.

If the S/D region 110 is an enhanced S/D structure formed by selective epitaxial growth, the top of the epitaxial part is high than the bottom of the gate stack, then the contact hole should be formed inside the S/D region 110 until the position that flushes with the bottom of the gate stack. Therefore, when the contact plug 620 is formed by filling the contact hole with contact metal, this contact metal can contact with the S/D region 110 through the part of sidewalls and the bottom of the contact hole, and lower the contact resistance by further increasing the contact area.

Optionally, metal can be deposited on the exposed S/D region 110 on the bottom of the contact hole, and annealing can be carried out to form a metal silicide 600. Specifically, first, pre-amorphization to the exposed S/D region 110 is carried out through the contact hole by ion implantation, amorphous compounds deposition, or selective growth to form a local amorphous silicon region. Then a uniform metal layer is formed in the S/D region 110 by metal sputtering or CVD. Preferably, this metal can be Ni, or other feasible metals, such as Ti, Co, or Cu, etc. Subsequently annealing is carried out to this semiconductor device. In other embodiments other annealing processes such as quick thermal annealing, spike annealing, etc. can be used. In the embodiment in present disclosure, an instantaneous annealing process is usually used to anneal the device, for example, micro-second laser annealing is carried out at temperatures above ˜1000 □ to make the deposited metal react with the amorphous compounds formed in the S/D region 110 to form a metal silicide 600, and finally the unreacted deposited metal can be removed by selective chemical corrosion. The amorphous compounds can be amorphous silicon, amorphous SiGe, or amorphous SiC. In current embodiment, the depth of the metal silicide 600 is 1 nm˜7 nm, such as 1 nm, 2 nm, or 7 nm. The advantage to form the metal silicide 600 is to further reduce the contact resistance by reducing the resistivity between the contact metal in the contact plug 620 and the S/D region 110.

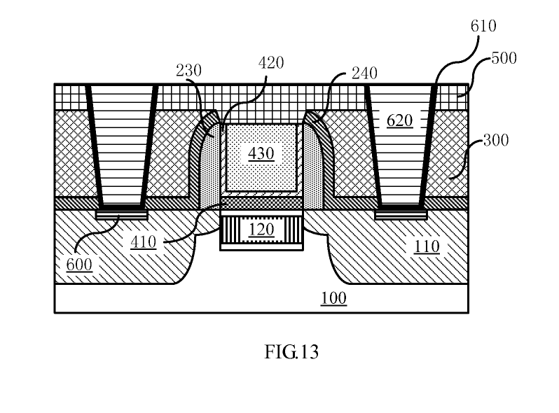

As illustrated in FIG. 13, a contact plug 620 is formed by filling the contact metal in the contact hole by deposition. The contact metal has a lower part that can be electrically connected with the exposed S/D region 110 in the substrate 100 (The “electrically connected” means the lower part of the contact metal can directly contact with the exposed S/D region 110 in the substrate 100, or form a substantial electrical communication with the exposed S/D region 110 in the substrate 100 through the formed metal silicide 600 on the exposed S/D region 110 in the substrate 100). The contact metal penetrates the stop layer 240, the first interlayer dielectric layer 300, and the second interlayer dielectric layer 500 through the contact hole, and the top of the contact metal is exposed.

Preferably, the material for the contact metal is W. According to the requirement in semiconductor manufacturing, the materials for the contact metal surely comprise but are not limited to W, Al, TiAl alloy, or combinations thereof. Optionally, a lining layer 610 can be chosen to form in the inner wall and the bottom of the contact hole before the contact metal is filled. The lining layer 610 can be deposited in the inner wall and the bottom of the contact hole by deposition processes including ALD, CVD, PVD, etc. The materials for the lining layer 610 can be Ti, TiN, Ta, TaN, Ru, or combinations thereof.

According to the semiconductor device manufacturing method provided in the present disclosure, the carrier mobility and the performance of the semiconductor device can be effectively improved by replacing Si material with Ge material to form a new channel region. By using in-situ doping method the damage caused by ion implantation can be effectively reduced. In addition, Ge doping will form a very steep doping profile and the short channel effect can be improved.

Although the exemplified embodiments and the advantages thereof have been illustrated in detail, it is understood that any modification, replacement and change can be made to these embodiments without departing from the spirit of the invention and the scope defined in the attaching claims. As to other examples, a skilled technician in the art can easily understand that the order of the process steps can be modified without falling outside the protection scope of the invention.

In addition, the application fields of the invention is limited to the process, mechanism, fabrication, material compositions, means, methods and/or steps in the particular embodiments as given in the description. From the disclosure of the invention, a skilled technician in the art can easily understand that, as for the process, mechanism, fabrication, material compositions, means, methods and/or steps at present or to be developed, which are carried out to realize substantially the same function or obtain substantially the same effects as the corresponding examples described according to the invention do, such process, mechanism, fabrication, material compositions, means, methods and/or steps can be applied according to the invention. Therefore, the claims attached to the invention are intended to encompass the process, mechanism, fabrication, material compositions, means, methods and/or steps into the protection scope thereof.

1. A method for manufacturing a semiconductor device, the characteristics of which comprising the following stages:
a) providing an substrate (100), forming a pseudo-gate stack and sidewalls (230) on the substrate (100), forming an S/D region (110) on both sides of the pseudo-gate stack, and forming a stop layer (240) and a first interlayer dielectric layer (300) covering the entire semiconductor device;
b) removing part of the stop layer (240) to expose the pseudo-gate stack, and further removing the pseudo-gate stack to expose the channel region;
c) etching the channel region to form a groove structure;
d) forming a new channel region in the groove structure to flush with the upper surface of the substrate (100), wherein the new channel region comprising successively from the substrate interface layer a buffer layer, a Ge layer (120), and a Si cap layer;
e) forming a gate stack.

2. The method according to claim 1, the characteristics of which is that it comprises:
conducting planarization to the first interlayer dielectric layer (300) after stage a).

3. The method according to claim 1, the characteristics of which is that stage e) comprises:
forming a dielectric layer (410) in the new channel region;
forming a high k dielectric layer (420) on the inner wall of the dielectric layer (410) and the sidewalls (230);
forming a metal gate (430).

4. The method according to claim 3, the characteristics of which is that the depth of the high k dielectric layer (420) is 1 nm˜3 nm.

5. The method according to claim 1, the characteristics of which is that it also comprises a stage after stage e):
f) forming a contact plug (620).

6. The method according to claim 5, the characteristics of which is that stage f) further comprises:
forming a second interlayer dielectric layer (500) covering the entire semiconductor device;
etching to remove part of the second interlayer dielectric layer (500), the first interlayer dielectric layer (300), and the stop layer (240) to form a contact hole to partially expose the S/D region (110)
forming a contact plug (620) by filling metal materials in the contact hole.

7. The method according to claim 6, the characteristics of which is that the depth of the second interlayer dielectric layer (500) is 10 nm˜50 nm.

8. The method according to claim 6, the characteristics of which is that a metal silicide (600) is formed before filling metal materials in the contact hole.

9. The method according to claim 1, the characteristics of which is that it also comprises in-situ doping the Ge layer when the new channel region is formed.

10. The method according to claim 1, the characteristics of which is that the buffer layer is made of SixGe1-x, where 0<x<1.

11. The method according to claim 1, the characteristics of which is that the depth of the stop layer (240) is 10 nm˜20 nm.

12. A semiconductor structure, comprising:
an substrate (100),forming a channel region groove, in which a buffer layer, a Ge layer (120), and a Si cap layer are filled;
a gate stack, which is formed on the Si cap layer;
sidewalls (230), which is formed on both sides of the gate stack;
an S/D region (110), which is formed in the substrate (100) on both sides of the channel region groove.

13. The semiconductor device according to claim 12, the characteristics of which is that it also comprises a stop layer (240) covering the S/D region (110) and the sidewalls (230), and a first interlayer dielectric layer (300) covering the stop layer (240).

14. The semiconductor device according to claim 12, the characteristics of which is that the buffer layer is made of SixGe1-x, where 0<x<1.

15. The semiconductor device according to claim 12, the characteristics of which is that the gate stack comprises a dielectric layer (410), a high k dielectric layer (420), and a metal gate (430).

16. The semiconductor device according to claim 15, the characteristics of which is that the depth of the high k dielectric layer (420) is 1 nm˜3 nm.

17. The semiconductor device according to claim 12, also comprising a second interlayer dielectric layer (500) and a contact plug (620), wherein, the second interlayer dielectric layer (500) covers the first interlayer dielectric layer (300) and the gate stack;
the contact plug (620) penetrates the second interlayer dielectric layer (500), the first interlayer dielectric layer (300), and the stop layer (240), and connects with the S/D region (110).

18. The semiconductor device according to claim 17, the characteristics of which is that the depth of the second interlayer dielectric layer (500) is 10 nm˜50 nm.

19. The semiconductor device according to claim 17, the characteristics of which is that it also comprises a metal silicide (600) between the contact plug (620) and the S/D region (110).

20. The semiconductor device according to claim 19, the characteristics of which is that the Ge layer (120) is in-situ doped.
